(19) United States
(12) Patent Application Publication
(10) Pub. No.: US 2013/0069646 A1
(43) Pub. Date: Mar. 21, 2013

(54) METHOD FOR THE COMPARATIVE ANALYSIS OF PROTEIN PREPARATIONS BY MEANS OF NUCLEAR MAGNETIC RESONANCE

(71) Applicants: Jean-Philippe Starck, Gougenheim (FR); Bruno Kieffer, Strasbourg (FR); Marc Quinternet, Dijon (FR)

(72) Inventors: Jean-Philippe Starck, Gougenheim (FR); Bruno Kieffer, Strasbourg (FR); Marc Quinternet, Dijon (FR)

(73) Assignee: NMRTEC, Illkirch Graffenstaden (FR)

(21) Appl. No.: 13/520,262

(22) PCT Filed: Dec. 30, 2010
(86) PCT No.: PCT/FR10/52936

§ 371 Date: Dec. 3, 2012

(30) Foreign Application Priority Data
Dec. 31, 2009 (FR) 0906427

(51) Int. Cl. G01R 33/465

(52) U.S. Cl. CPC G01R 33/465
USPC 324/309

(57) ABSTRACT

The invention relates to a method for the comparative analysis and control of the quality of a protein preparation by means of nuclear magnetic resonance (NMR) spectrometry. This method can be used to compare three-dimensional protein conformations in different protein preparations without requiring the samples to undergo any particular preparation. In particular, the method can be used to determine if a selected protein is in the same three-dimensional conformation in different protein preparations, if it is degraded in the formulation or if it is interacting with some of the excipients present. Specifically, the method can be used for the analysis and control of the quality of therapeutic compounds, particularly biodrugs or biosimilars, in different samples, without altering said samples.

The present invention relates to a method for the comparative analysis and the quality control of a protein preparation by means of nuclear magnetic resonance (NMR). This method allows the comparison of three-dimensional protein conformations in various protein preparations without any particular preparation of the samples being necessary. In particular this method allows determining if a selected protein is in the same three-dimensional conformation in various protein preparations or if it is degraded in the formulation or if it is interacting with some of the excipients that are present. This method allows in particular the analysis and the quality control of therapeutic compounds, particularly biodrugs or biosimilars, in various samples, and this without deteriorating said samples.

The proteins are constituted by polypeptidic chains, or successions of amino-acids, more or less long which one can determine the sequence. Such a succession of amino-acids linked by peptidic bonds constitutes the primary structure of a protein. However, each protein has also a three-dimensional structure, or conformation, that is established and maintained by other types of bonds than the peptidic bonds. Said bonds are provided in general by disulphide bonds, ionic bonds, hydrogen bonds or hydrophobic interactions. This pertains to the field of structural biochemistry, field where one speaks then about secondary structure, tertiary, even quaternary, which confers to each protein its particular properties.

Each protein this has a proteinic conformation or three-dimensional structure that is its own. This conformation is likely to be upset or disrupted without any peptidic bond being broken. In fact the other bonds are affected and this leads to a modification in proteinic conformation that one call also denaturation. The denaturation can be reversible or irreversible, complete or partial, according to the nature and the number of destabilized bonds; this inevitably affects the physical and biological properties of the protein. Such a proteinic denaturation can be caused by a whole variety of physical and/or chemical agents such as heat, cold, freezing, ultraviolet and ionizing radiations, variations of pH, detergents, organic solvents, a urea or guanidine solution, but also by a dilution or the agitation of a proteinic preparation. The analysis of proteinic structures can thus be very delicate considering that the proteinic conformations are very sensitive, including with agitation. Moreover, a proteinic preparation can contain several proteins, it is thus often necessary to carry out in the first place an isolation and a purification of the protein of interest.

The techniques making it possible to determine the primary structures, secondary, etc. are no well known by one skilled in the art. The analysis of the primary structure of proteins is generally done by the analysis of the amino-acids composition by chromatography (by ion exchange, in gas phase or of adsorption) or by amino-acids sequencing by calling upon recurrent chemical or enzymatic methods releasing the amino-acids one by one starting from the C terminal or N terminal end or more recently by using methods implementing the mass spectrometry. The secondary, tertiary and quaternary structures are determined by analysis of the diagrams of X-rays diffraction or by nuclear magnetic resonance (NMR). These techniques require however often at least the purification and the concentration of proteins if not their denaturation and consequently the loss of the sample, or proteinic preparation, to analyse. The analysis of samples by nuclear magnetic resonance (NMR) has the advantage to allow the study of a protein of interest without denaturing it. The principle of the use of NMR in the proteinic analysis consists in placing a protein of interest in solution in an intense magnetic field. The spins of the atomic nuclei composing the protein of interest will then be directed along the main axis of the magnetic field. It is then possible to disturb the state of balance of these spins thanks to a series of electromagnetic impulses and to measure the induced current at the time of the return to balance. The registered NMR signal contains the combination of the whole contributions of the various atoms in solution; said whole also being called spectrum (Cavanagh et al., Protein NMR Spectroscopy: Principles and Practice, Academic Press, December 1995). According to the selected NMR method, one will obtain a spectrum with one dimension (1D NMR), with two dimensions (2D NMR) or with three dimensions (3D). The level of information revealed by each spectrum will depend on the selected NMR method.

Several analysis methods applicable to the study of proteinic conformations and implementing the NMR spectrometry were described to date. One can mention in particular the method DOSY, the methods NOESY, SOFAST, COSY, TOCSY, HSQC, HNCA, HNCO, HNCOCA, HCCH TOCSY, HCCH COSY ameliorated or not by the TROSY variant, like any sequence of NMR recording allowing to establish correlations between two or several nuclei of the protein of interest (Sattler et al., Prog Nuc Mag Reson Spectro, 1999, vol. 34(2) p. 93-158). Most commonly employed within this particular framework are DOSY ¹H methods (C. S. Johnson Jr., Diffusion ordered nuclear magnetic resonance spectroscopy: principles and applications, Prog. NMR Spectrosc. 34 (1999) 203-256; Balayssac S. et al., J. Magn. Reson. 2009, 196, 78-83) et SOFAST (Schanda et al. J Am Chem Soc (2005) vol. 127 (22) p. 8014-15).

The application of the NMR methods to the analysis of proteinic conformations allows in particular the analysis of biodrugs. The biodrugs have been developed for more than twenty years and can be classified in various categories for example: the hormonal products (growth hormones, erythropoietin, and insulin), the immunomodulators (beta-interferon), the monoclonal antibodies, the modulators of blood coagulation (VIII and IX factors), the enzymes and the vaccines. The biodrugs can also be obtained by various methods and are sensitive to several external factors. There is thus a very particular interest to be able to analyse them quickly directly in the medium where they are, in particular to determine if their conformation is functional (Knäblein J., Modern Biopharmaceuticals: Design, Development and Optimization, Wiley V C, February 2008). Among the drugs available on the European market, more than one hundred meet the definition of biodrugs above. There exists for example several biodrugs marketed or having been marketed in Europe, which are derived from insulin: Actrapid® (Boehringer Ingelheim), Apidra® Insuman® et Lantus® (Sanofi-Aventis), Humalog® et Umuline rapide® (Eli Lilly), Insulatard® Levemir® Mixtard® Monotard® Novomix® Novorapid® Ultratard® and Velosuline® (Novo Nordisk). There exists also several biodrugs derived from erythropoietin: Eprex® (Janssen Cilag), Neorecormon® (Roche), and Aranesp® (Amgen). There exists also several drugs derived from the growth hormone: Humatrope® (Eli Lilly), Norditropine® (Novo Nordisk) and Genotonorm® (Pfizer). This list is not exhaustive and is given only as an example.

Following the development of biodrugs the concept of biosimilars drug or treatment with biosimilar has appeared. These biosimilars are compounds for therapeutic use that succeed a biodrug whose legal monopoly of exploitation has expired. The concept of “treatment with biosimilars” was integrated in the European law in 2003 (see also the European Guideline CHMP/42832/05). In this particular case, there is some interest to have means of analysis to determine if a biosimilar id identical to the biodrug to which it succeeds as well as regards to its primary structure as of its three-dimensional structure. To date, there exists several biosimilar drugs available on the European market in four groups: erythropoietin, growth hormone, insulin and G-CSF (for granulocyte-colony stimulating factor). One will quote for example in the field of somatotropins Omnitrope® (Sandoz®) and Valtropin® (Biopartners®) which are biosimilars of Genotropin® ou Genotonorm® (Pfizer®), in the field of erythropoietins alpha Binocrit® (Sandoz®), Epoetin alfa Hexal (Hexal®) and Abseamed (Medice Arzneimittel Pütter GmbH&Co) which are biosimilars of d'Eprex® (Janssen Cilag) or also in the field of filgrastim Biograstim® (CT Arzneimittel GmbH), Filgrastim Ratiopharm (Ratiopharm GmbH), Ratiograstim® (Ratiopharm GmbH), Tevagrastim® (Teva Generics GmbH) which are biosimilars of Neupogen® (Amgen®).

Many studies of proteinic conformations implementing NMR have been described in the prior art (Cavanagh et al., Protein NMR Spectroscopy: Principles and Practice, Academic Press, December 1995). These experiments describe in general the elucidation or the confirmation of the proteininc conformation of a protein of interest by use of NMR spectra, once the sequence of the protein is known, of a protein of interest in its different conformations (active in opposition to inactive, stable in opposition to unstable, etc.). The NMR allows also determining which is the quaternary structure of a protein: dimer, tetramer, etc. Indeed, the biological activity of a protein often lies in its oligomeric structure, namely the situation in which several polypeptidic chains join in a specific way. The implementation of the NMR makes it possible to study this oligomerization according to the physicochemical constraints imposed on a protein since it does not impose the denaturation of the protein of interest.

The European patent EP0975954 describes a screening process to identify the presence of compounds that binds a determined target biomolecule. This process consists of the following stages: a) to generate a first monodimensional NMR spectrum T₂ filtered or by diffusion of a compound or of a mixture of chemical compounds; b) to expose the compound or the mixture of chemical compounds to a target molecule; c) to generate a second monodimensional NMR spectrum T₂ filtered or by diffusion of said compound or of said mixture of chemical compounds when it is exposed to the target molecule in stage b); and d) to compare said first and second monodimensional NMR spectra T₂ filtered or by diffusion in order to determine the differences between said first and said second NMR spectra, the differences identifying the presence of one or several compounds among said first compound or said mixture of chemical compounds respectively, which are ligands that have bound the target molecule. This screening process implementing the NMR makes it possible to identify a binding between a biomolecule, potentially a protein, and a ligand of this biomolecule. The NMR is used here for the realization of screening campaigns making it possible to identify ligands; it is not at all question of applying NMR to the qualitative analysis of primary, secondary, tertiary and quaternary structures of biomolecules.

The international application WO2008/128219 describes a method for the comparative analysis of proteinic conformations implementing NMR ¹H-¹H NOESY spectra. In this application only the ¹H-¹H NOESY method is described for the characterization of proteins in different therapeutic formulations. Only the frequency displacements of the hydrogen atoms are detected. No other experiment is realized to reach an additional level of information. However it is well-known from one skilled in the art that in a therapeutic formulation, the protein of interest consisting generally of the active ingredient of the formulation, is mixed with excipients of the buffer type, binders, diluents, disintegrant, sweeteners, etc. that one find in general in greater concentration than said protein of interest. There are thus several drawbacks to this analysis method. Indeed, under the described conditions, the signal detected with the ¹H-¹H NOESY method is likely to be masked by the signal of the excipients. Moreover, according to the number of amino-acids constituting the protein of interest, the ¹H-¹H NOESY spectrum can become so complex that it will not be easily interpreted. Lastly, the pH of the therapeutic formulation to study will also have its importance insofar as with certain pH, especially those higher than 7.5, the protein of interest will not give any detectable signal. A direct analysis on a sample collected from a therapeutic formulation will thus not be possible. Indeed, to overcome all these drawbacks, it will initially be necessary to purify the protein of interest then to concentrate it, or then to find a way to filter the signals in order to be able to extract the specific signal of the protein of interest. In addition, it is preferable that the protein of interest is not too large in order to be able to discriminate the individual contributions in the used spectrum. Finally, it is also advisable to find a way to control the external parameters such as pH of the sample.

The existing methods implementing the NMR spectrometry for the analysis of proteins thus require several stages of preparation of the samples (purification, concentration, etc.). They make it possible to elucidate the structure of certain proteins and to run screening in order to find potential ligands of these proteins. As evoked here-above, the therapeutic compositions contain an active substance but also other compounds such as excipients as well as other elements of proteinic nature or not. It thus does not seem easy to adapt these methods implementing NMR to a fast comparative analysis and a reliable quality control of therapeutic compositions containing biodrugs and/or biosimilars.

The present invention proposes to provide a reliable and fast alternative to this situation. The method of comparative analysis and of quality control of the therapeutic compositions object of the present invention is very sensitive and allows a direct analysis from the selected therapeutic formulation. Indeed, this new method of comparative analysis and of quality control allows the analysis of unlabelled proteins, of proteins of any size, the specific filtering of the signal corresponding to the protein of interest, as well as the freedom from the control of the external parameters such as pH.

The present invention consists in a method for the comparative analysis and the quality control of therapeutic compositions, implementing the nuclear magnetic resonance (NMR) spectrometry, characterized in that it consists of the following steps:
a) to select at least two different proteinic preparations containing a biodrug;
b) to establish the spectral signature of the biodrug in the first proteinic preparation from at least two spectra of nuclear magnetic resonance;
c) to establish the spectral signature of the biodrug in the second proteinic preparation from at least two spectra of nuclear magnetic resonance;
d) to compare the spectral signatures of the biodrug in the first and in the second proteinic preparations;
e) to determine from the spectral signatures obtained during the steps b) and c) if the biodrug is identical in the first proteinic preparation and in the second proteinic preparation.

This innovative method makes it possible to study, from the detection and the analysis of frequency displacements, the primary structure of the protein of interest and in particular of a biodrug, in the studied samples, its conformational integrity, its oligomerization state as well as to detect the presence or the absence of excipients or of any other element of a proteinic or non-proteinic nature. The fact of cumulating information provided by at least two spectra realized from a same proteinic sample, but according to different acquisition methods, makes it possible to deduce in an unquestionable way information about the conformation of the biodrug, the excipients or any other element of a proteinic or non-proteinic nature.

This new method does not require any stage of preliminary conditioning of the sample to analyse. Indeed, in the implementation of this method, the therapeutic compositions are used directly, without stage of purification or of concentration of the biodrug, and without labelling of said biodrug. The therapeutic composition is put in solution then placed on the support of reading and analysis specific to the NMR device used. This method allows in particular working directly on the galenic formula of the therapeutic compositions containing a protein of interest and in particular a biodrug.

Within the framework of a direct analysis starting from a commercial formulation of a drug as an example, if said commercial formulation presented a concentration of biodrug in insufficient quantity compared to the detection threshold of the NMR signal, then it would be necessary to increase the field (pass from 600 MHz to 800, 900 or 1000 MHz) and/or to use the method of dynamic nuclear polarization (like that marketed by Oxford Instrument®) or any other method of increasing the polarization.

The words defined below are used as well in the singular as in the plural.

By “amino-acid” one understands in the present invention a compound comprising a carboxylic acid function and an amine function on the same carbon atom. This includes the twenty amino-acids constitutive of all the proteins as well as all other amino-acids being in a free state and having an important metabolic role, and those constituting small peptides of less than twenty amino-acids manufactured by micro-organisms and plants only.

By “biodrug” is meant in the present invention a compound for therapeutic use of which the active substance is issued from the biotechnologies such as the monoclonal antibodies, the recombining proteins (the enzymes and cytokines as examples), the gene therapy compounds and the stem cells, but also the more older compounds and treatments such as vaccines, blood products, toxins and antisera. Are also included in this definition the peptides and the polynucleosides. The concept of biodrug has a meaning in opposition to the drugs made up of small chemical entities.

By “biosimilar” one understand in the present invention a compound for therapeutic use that succeed to a biodrug which exploitation, and in particular the manufacturing process, do not be subject to a legal monopoly. The biosimilars are also issued from biotechnologies and present similarities in terms of quality, of security and of efficacy compared to the biodrug to which it is being compared.

By “therapeutic composition” one understand in the present invention a preparation having curative or preventive properties with regards to human or animal pathologies, which can be used and/or be administered in order to restore, correct or modify the physiological functions implied in a pathological state, by exerting a pharmacological, immunological or metabolic action.

By “proteinic conformation” or “three-dimensional conformation of a protein” is meant the three-dimensional structure of the protein of interest, that is to say not only the primary, secondary or tertiary structure of said protein but also, if the case arises, its quaternary structure.

By “nucleoside” one understands in the present invention the molecule composed by the binding of a puric base (such as adenine and guanine) or a pyrimidic base (such as the uracil, the cytosine, the thymidine) with the ribose or the deoxyribose. Among the principal nucleosides one can cite the adenosine and the deoxyadenosine, the guanosine and the deoxyguanosine, the uridine and the deoxyuridine, the cytidine and the deoxycytidine, as well as the thymine ribonucleoside and the deoxythymidine (also called thymidine).

By “peptide” one understands in the present invention a sequence of at least two amino-acids bound between them by peptide bonds, what encompasses the oligopeptides or dipeptides formed by the union of two amino-acids and the tripeptides, as well as the polypeptides (starting from the tetrapeptides). The natural peptides are formed by various amino-acids but one can synthesize homopeptides (such as triglycine, or the polyphenylalanin, etc.). The peptides can have various structures: linear peptides, ramified peptides, cyclic peptides and semi-cyclic peptides. According to their structure, the peptides will include other bonds in addition to peptide bonds.

By “proteinic preparation” one understands in the present invention a mixture of proteins, identical or different, obtained according to a given method of production. This includes the therapeutic formulations as marketed by the pharmaceutical laboratories (likely to contain also excipients such as buffers, binders, diluents, disintegrants, sweeteners, etc.

This also includes any preparation of a proteinic mixture obtained by isolation, taking away or any biotechnological process known from one skilled in the art, namely in particular the solubilisation, the concentration, the purification, etc.

By “protein” one understands in the present invention a polypeptide involving one or several peptide bonds linking two or more amino-acids. It is commonly allowed that the proteins are polypeptides having a molecular mass higher than 10 000 and that do not dialyse through a membrane of cellophane (General Biochemistry, J.-H. WEIL, Dunod, 11^{th} edition, Chapter 1, page 17). A protein can include a portion that is not made up of one or several amino-acids (e.g.: glycoproteins) and can in addition be truncated or modified. It is obvious for one skilled in the art that a protein can be a synthetic polypeptide sequence or natural as secreted by a cell, or simply a functional portion of such a protein.

By “1D NMR” one understands the nuclear magnetic resonance with only one dimension or monodimensional.

By “2D NMR” one understands the nuclear magnetic resonance with two dimensions or bidimensional (experiment of the COSY, DOSY, NOESY, HSQC, HMBC, etc. type).

By “3D NMR” one understands the nuclear magnetic resonance with three dimensions or tridimensional (experiment of the HNCO type, etc.)

By “spectral signature” one understands the whole resonances of the cores observed for a protein of interest under given conditions (for example field, solvent, temperature . . . ).

According to the nature of the protein of interest and in order to obtain a sufficient level of information to realize a reliable comparative analysis of proteinic conformations, it is sometimes preferable to have the information provided by at least one two-dimensional NMR spectrum (2D NMR). Indeed, the present invention is likely to use a large variety of spectra to obtain the spectral signature of a protein. The two essential criteria for the choice of the type of experiment to realize are the sensitivity, which must be adapted to the quantity of protein present in the formulation, and the degree of ambiguity of the spectral signature obtained. To reach the maximum sensitivity, the acquisition of information will be made by recording the spectra at the proton frequency, the most sensitive core in NMR. It is then possible to gain sensitivity while using on one hand a spectrometer equipped with a cryogenic probe, and on the other hand, acquisition methods allowing to draw advantage from the particular properties of relaxation of the macromolecules. In a general manner, and in order to reduce the degree of ambiguity of the spectral signature, one will record two-dimensional spectra or of higher dimensionality. Consequently, in a preferred embodiment, the present invention describes a method for the comparative analysis and the quality control of therapeutic compositions, implementing the nuclear magnetic resonance (NMR) spectrometry, characterized in that it consists of the following stages:
a) to select at least two different proteinic preparations containing a biodrug;
b) to establish the spectral signature of the biodrug in the first proteinic preparation from at least two spectra of nuclear magnetic resonance;
c) to establish the spectral signature of the biodrug in the second proteinic preparation from at least two spectra of nuclear magnetic resonance;
d) to compare the spectral signatures of the biodrug in the first and in the second proteinic preparations;
e) to determine from the spectral signatures obtained during the steps b) and c) if the biodrug is identical in the first proteinic preparation and in the second proteinic preparation.
   wherein at least one nuclear resonance magnetic (NMR) spectrum realized during step b) from one of the selected proteinic preparations implements a two-dimensional nuclear magnetic resonance (NMR) method called 2D NMR.

In a different embodiment, the present invention describes a method for the comparative analysis and the quality control of therapeutic compositions, implementing the nuclear magnetic resonance (NMR) spectrometry, characterized in that it consists of the following stages:
a) to select at least two different proteinic preparations containing a biodrug;
b) to establish the spectral signature of the biodrug in the first proteinic preparation from at least two spectra of nuclear magnetic resonance;
c) to establish the spectral signature of the biodrug in the second proteinic preparation from at least two spectra of nuclear magnetic resonance;
d) to compare the spectral signatures of the biodrug in the first and in the second proteinic preparations;
e) to determine from the spectral signatures obtained during the steps b) and c) if the biodrug is identical in the first proteinic preparation and in the second proteinic preparation.
   wherein at least one nuclear resonance magnetic (NMR) spectrum realized during step c) from one of the selected proteinic preparations implements a two-dimensional nuclear magnetic resonance (NMR) method called 2D NMR.

The interpretation of the information provided by the spectra obtained further to the implementation of the method below makes it possible to detect in the therapeutic composition the presence or the absence of excipients, the state of the biodrug and in particular its conformation, as well as potential displacements of frequency, even light, if the biodrug is different in the first proteinic preparation and in the second proteinic preparation. If the biodrug is identical and in the same conformational state in both proteinic preparations, no displacement of frequency is observed.

According to a preferred embodiment, the method for comparison implements the DOSY method, the NOESY, SOFAST, COSY, TOCSY, HSQC, HNCA, HNCO, HNCOCA, HCCH TOCSY HCCH COSY methods improved or not by the TROSY alternative, as well as any recording sequence of nuclear magnetic resonance that allows to establish correlations between two or more cores of the biodrug.

According to another embodiment, the method of analysis according to the present invention is characterized in that said method of two-dimensional nuclear magnetic resonance (2D NMR) is selected among the DOSY and the SOFAST methods, possibly in combination with the TROSY alternative. The NMR experiment implemented during step b) and/or during step c) is preferentially selected among the following experiments: DOSY and SOFAST. According to another embodiment, the method according to the invention is characterized in that the two-dimensional NMR (2D NMR) method used is the DOSY method. Lastly, according to a preferred embodiment, the method of analysis is characterized in that the two-dimensional NMR method used is the SOFAST method, possibly in combination with the TROSY alternative.

In a particular embodiment, the method for the comparative analysis and the quality control of therapeutic compositions implementing the nuclear magnetic resonance (NMR) spectrometry according to the invention is characterized in that it consists of the following stages:
a) to select at least two different proteinic preparations containing a biodrug;
b) to establish the spectral signature of the biodrug in the first proteinic preparation from at least two spectra of nuclear magnetic resonance;
c) to establish the spectral signature of the biodrug in the second proteinic preparation from at least two spectra of nuclear magnetic resonance, said spectra being realized according to the same methods of nuclear magnetic resonance (NMR) than during step b);
d) to compare the spectral signatures of the biodrug in the first and in the second proteinic preparations by superposing the spectra realized during steps b) and c);
e) to determine from the spectral signatures obtained during the steps b) and c) if the biodrug is identical in the first proteinic preparation and in the second proteinic preparation.

Indeed, the possibility to superpose the spectra realized further to the implementation of the same NMR methods allows a faster interpretation of the results. One realizes for example a DOSY experiment and a SOFAST experiment, meaning two spectra, during step b) from a sample containing the protein of interest. One realizes then the same DOSY and SOFAST experiments, meaning two spectra, on the second proteinic sample during step c). A software for the exploitation of the NMR spectra (for example NMRnotebook®) allows then the superposition of said spectra, which are four and which will be compared two to two. The interpretation of information thus provided allows then to detect the presence or the absence of excipients, the state of the biodrug and in particular its conformation, as well as potential displacements of frequency, even light, if the biodrug is different in the first proteinic preparation and in the second proteinic preparation. If the biodrug is identical and in the same conformational state in both proteinic preparations, the spectra are superposing themselves completely and no displacement of frequency is observed.

In a preferred embodiment, the method of analysis and of quality control of a therapeutic composition, implementing the nuclear magnetic resonance (NMR) according to the invention is characterized in that it consists of the following steps:
a) to select at least two various proteinic preparations containing a biodrug;
b) to establish the spectral signature of the biodrug in the first proteinic preparation from at least two nuclear magnetic resonance spectra;
c) to establish the spectral signature of the biodrug in the second proteinic preparation form at least two nuclear magnetic resonance spectra, said spectra being realized according to the same methods of nuclear magnetic resonance than during step b);
d) to compare the spectral signatures of the biodrug in the first and in the second proteinic preparation by superposing the spectra realized during steps b) and c);
e) to determine from the spectral signatures obtained during steps b) and c) if the biodrug is identical in the first proteinic preparation and in the second proteinic preparation;
   wherein at least one NMR spectrum realized from one of the selected proteinic preparations implements a two-dimensional nuclear magnetic resonance method called 2D NMR.

As evoked above, the present invention is likely to use a large variety of spectra to obtain the spectral signature of a biodrug. In particular, one will use in certain cases the possibility of refining the widths of the lines by using the crossed correlation phenomenon between two mechanisms of relaxation (experiment of the TROSY type), or the possibility of optimizing the rate of repetition of the experiments by using the properties of specific longitudinal relaxation of certain protons groups within the protein (such as amides protons or those of the methyls groups). One will also be able to use spectra of correlation between the protons of the protein and some hetero-cores such as nitrogen 15 or carbon 13. The low natural abundance of these isotopes of nitrogen and of carbon reduces the sensitivity of the experiments but increases the specificity of the spectral signatures obtained. The balance between specificity and sensitivity must be adapted to each family of drugs. The quaternary structure (oligomerization degree of the protein of interest) as well as the solvent composition will be obtained by recording of spectra allowing to highlight the speeds of translational diffusion of the molecules. These data can, for example, be obtained using DOSY spectra. According to a particular embodiment, the method of analysis above is characterized in that said method of two-dimensional NMR (2D NMR) is selected from the DOSY method, the NOESY, SOFAST, COSY, TOCSY, HSQC, HNCA, HNCO, HNCOCA, HCCH TOCSY HCCH COSY methods improved or not by the TROSY alternative, as well as any recording sequence of nuclear magnetic resonance that allows to establish correlations between two or more cores of the biodrug. The NMR experiment implemented is preferentially selected from the following experiments: DOSY and SOFAST. According to another particular embodiment, the method according to the invention is characterized in that the two-dimensional NMR method used is the DOSY method. Lastly, according to a preferred embodiment, the method of analysis is characterized in that the two-dimensional NMR method used is the SOFAST method, possibly improved by the TROSY alternative.

In order to obtain an additional information level, the present invention provides an method for the analysis and the quality control as detailed above, in which the steps a) d) and e) are unchanged in comparison with the general method and which consists of the following steps:
b) to realize at least two two-dimensional nuclear magnetic resonance (2D NMR) spectra from the first proteinic preparation;
c) to realize at least two two-dimensional nuclear magnetic resonance (2D NMR) spectra from the second proteinic preparation.

In a particular embodiment, the present invention consists of a method for the comparative analysis and the quality control of therapeutic compositions, implementing the nuclear magnetic resonance (NMR) spectrometry, characterized in that it consists of the following steps:
a) to select at least two different proteinic preparations containing a biodrug;
b) to establish the spectral signature of the biodrug in the first proteinic preparation from a NMR DOSY spectrum and a NMR SOFAST spectrum;
c) to establish the spectral signature of the biodrug in the second proteinic preparation from a NMR DOSY spectrum and a NMR SOFAST spectrum;
d) to compare the spectral signatures of the biodrug in the first and in the second proteinic preparations;
e) to determine from the spectral signatures obtained during steps b) and c) if the biodrug is identical in the first proteinic preparation and in the second proteinic preparation.

As this is described above, the innovative method object of the present invention takes on a very particular interest in the case of the study of biodrugs or of biosimilars. According to a particular embodiment, the method for the comparative analysis and the control of quality of therapeutic compositions implementing the nuclear magnetic resonance spectrometry (NMR) according to the invention is characterized in that the comparative analysis is based on a biosimilar. In this particular embodiment the present invention relates to a method for the comparative analysis and the control of quality of therapeutic compositions, implementing the nuclear magnetic resonance spectrometry (NMR), characterized in that it consists of the following steps:
a) to select at least two different proteinic preparations containing a biosimilar;
b) to establish the spectral signature of the biosimilar in the first proteinic preparation from at least two spectra of nuclear magnetic resonance;
c) to establish the spectral signature of the biosimilar in the second proteinic preparation from at least two spectra of nuclear magnetic resonance;
d) to compare the spectral signatures of the biosimilar in the first and in the second proteinic preparations;
e) to determine from the spectral signatures obtained during the steps b) and c) if the biosimilar is identical in the first proteinic preparation and in the second proteinic preparation.

It can also be envisaged to study a proteinic preparation containing a biodrug derived from a given compound by comparison to a proteinic preparation containing a biosimilar derived of that same compound. One will be able to for example use within the framework of a study relating to the filgrastim: during step b) a proteinic preparation containing the therapeutic compound Neupogen® (Amgen) and during step c) a proteinic preparation containing the therapeutic compound Tevagrastim® (Teva Generics GmbH); within the framework of a study relating to the somatotropins: during step b) a proteinic preparation containing the therapeutic compound Genotropin® (Pfizer) and during step c) a proteinic preparation containing the therapeutic compound Omnitrope® (Sandoz). The present invention describes also a method for the comparative analysis of proteinic conformations implementing the nuclear magnetic resonance (NMR) spectrometry characterized in that it consists of the following steps:
a) to select at least two different proteinic preparations containing respectively a biodrug and a biosimilar;
b) to establish the spectral signature of the biodrug in the first proteinic preparation containing a biodrug from at least two spectra of nuclear magnetic resonance;
c) to establish the spectral signature of the biosimilar in the second proteinic preparation containing a biosimilar from at least two spectra of nuclear magnetic resonance;
d) to compare the spectral signatures of the biodrug and the biosimilar in the first and in the second proteinic preparations;
e) to determine from the spectral signatures obtained during the steps b) and c) if the biodrug and the biosimilar are identical in the first proteinic preparation and in the second proteinic preparation.

In a particular embodiment according to the method described above the biodrug is selected from: the hormonal products (growth hormone, erythropoietin, and insulin), the immunomodulators (beta-interferon), the monoclonal antibodies, the blood coagulation factors (VIII and IX factors), the enzymes and the vaccines. In a preferred manner, the biodrug is selected from the hormonal products: insulin, growth hormone and erythropoietin. In a preferred embodiment the protein of interest is insulin.

The relevance and the effectiveness of the method for the comparative analysis and the quality control of the biodrugs according to the invention were established at the time of comparative studies on insulin and its biodrugs. Consequently, the present invention describes a method for the comparative analysis and the quality control of therapeutic compositions containing insulin, implementing the nuclear magnetic resonance (NMR) spectrometry, characterized in that it consist of the following steps:
a) to select at least two different proteinic preparations containing insulin;
b) to establish the spectral signature of the insulin in the first proteinic preparation from at least two spectra of nuclear magnetic resonance;
c) to establish the spectral signature of the insulin in the second proteinic preparation from at least two spectra of nuclear magnetic resonance;
d) to compare the spectral signatures of the insulin in the first and in the second proteinic preparations;
e) to determine from the spectral signatures obtained during the steps b) and c) if the insulin is identical in the first proteinic preparation and in the second proteinic preparation.

If the spectra obtained from the first proteinic preparation during step b) and from the second proteinic preparation obtained during step c) show displacements of frequencies found significant at the insulin level, then the insulins in presence are considered as different. If the spectra are superimposable, then the insulins in presence are considered as identical. Moreover, the spectra will also inform on the primary structure on the insulin in the studied samples, its proteinic conformation, its oligomeric structure, as well as the presence or the absence of excipients.

In a first embodiment, in the method described above in its application to insulin, at least one NMR spectrum realized during step b), or during step c) from one of the proteinic preparations selected, implements a two-dimensional NMR method called 2D NMR.

In another embodiment, the method described above in its application to insulin, at least one NMR spectrum realized during steps b) and c) from both proteinic preparations selected, implements a two-dimensional NMR method called 2D NMR.

In a preferred embodiment, the method described above in its application to insulin, the experiments realized during step c) are identical to those realized during step b). For example, if NMR experiments DOSY and SOFAST are realized during step b), then NMR experiments DOSY and SOFAST will be realized during step c).

In a particular embodiment, the method described above in its application to insulin is characterized in that it consists of the following stages:
a) to select at least two different proteinic preparations containing insulin;
b) to establish the spectral signature of the insulin in the first proteinic preparation from at least two spectra of nuclear magnetic resonance;
c) to establish the spectral signature of the insulin in the second proteinic preparation from at least two spectra of nuclear magnetic resonance;
d) to compare the spectral signatures of insulin in the first and in the second proteinic preparations;
e) to determine from the spectral signatures obtained during the steps b) and c) if the insulin is identical in the first proteinic preparation and in the second proteinic preparation.

In a preferred embodiment according to the method above, said method is characterized in that it consists of the following steps:
a) to select at least two different proteinic preparations containing insulin;
b) to establish the spectral signature of insulin in the first proteinic preparation from one NMR DOSY spectrum and one NMR SOFAST spectrum;
c) to establish the spectral signature of insulin in the second proteinic preparation from one NMR DOSY spectrum and one NMR SOFAST spectrum;
d) to compare the spectral signatures of insulin in the first and in the second proteinic preparations;
e) to determine from the spectral signatures obtained during the steps b) and c) if the insulin is identical in the first proteinic preparation and in the second proteinic preparation.

The present invention describes also a method for the comparative analysis and the control of quality of therapeutic compositions containing growth hormone, implementing the nuclear magnetic resonance (NMR) spectrometry, characterized in that it consists of the following steps:
a) to select at least two different proteinic preparations containing growth hormone;
b) to establish the spectral signature of the growth hormone in the first proteinic preparation from at least two spectra of nuclear magnetic resonance;
c) to establish the spectral signature of the growth hormone in the second proteinic preparation from at least two spectra of nuclear magnetic resonance;
d) to compare the spectral signatures of growth hormone in the first and in the second proteinic preparations;
e) to determine from the spectral signatures obtained during the steps b) and c) if the growth hormone is identical in the first proteinic preparation and in the second proteinic preparation.

If the spectra obtained from the first proteinic preparation during step b) and from the second proteinic preparation during step c) show displacements of frequency considered significant at the level of growth hormone, then the growth hormones in presence will be considered as different. If the spectra are superimposable, then the growth hormones in presence are identical. In addition, the spectra will also inform about the primary structure of the growth hormone in the studied sample, its proteinic conformation, its oligomeric structure, as well as the presence or the absence of excipients or of any other element of a proteinic or non-proteinic nature.

The present invention also relates to a method for the comparative analysis of proteinic conformations implementing the nuclear magnetic resonance (NMR) spectrometry in which the protein of interest is the growth hormone.

Moreover, all the applications described above implement a comparison between at least two samples, therefore at least two therapeutic compositions. It can however be envisaged to proceed with comparisons between more than two therapeutic compositions.

The present invention is illustrated by the examples and figures below:

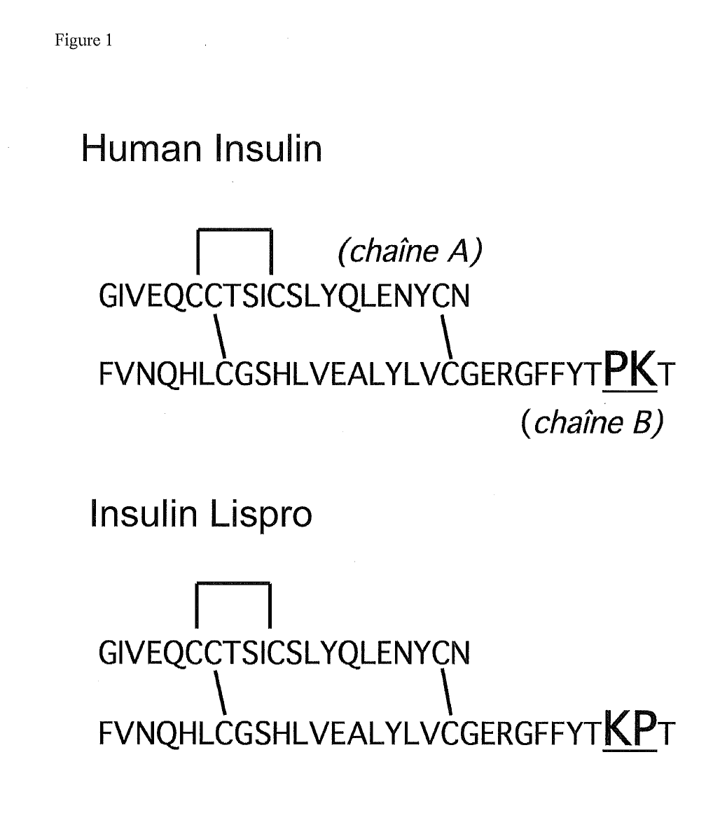

FIG. 1 presents the amino-acids sequence of human insulin lispro. The bold lines represent the three disulfide bonds. The differences between the two sequences are underlined and the concerned amino-acids (lysine and proline) are presented in bold.

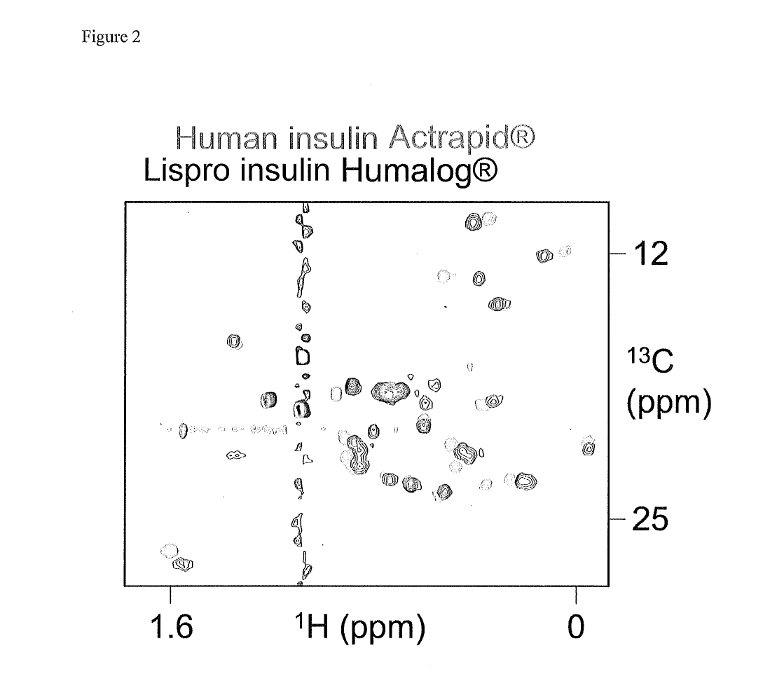

FIG. 2 presents the overlaying of SOFAST-HMQC ¹H-¹³C spectra of human insulin Actrapid® (bright line) and the lispro insulin Humalog® (dark line).

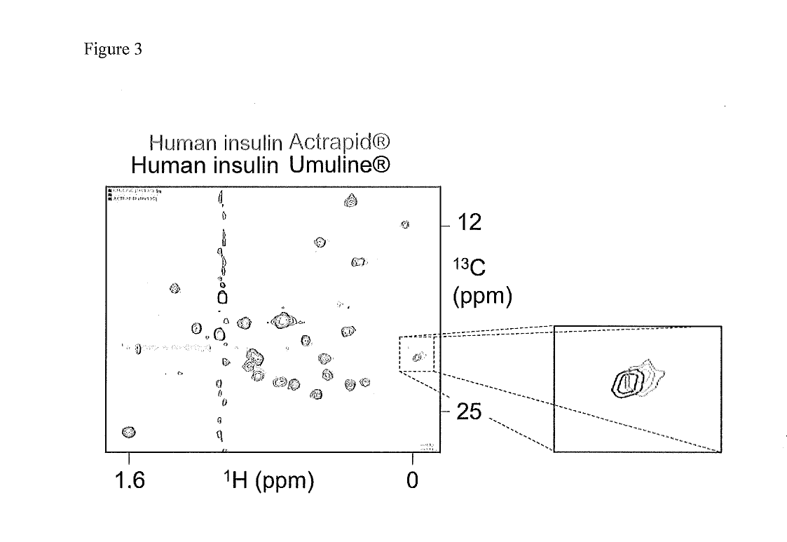

FIG. 3 presents the superposition of the SOFAST-HMQC ¹H-¹³C spectrum of human insulin Actrapid® (light line) and human insulin Umuline rapide® (dark line). In the insert is highlighted a light displacement of frequency.

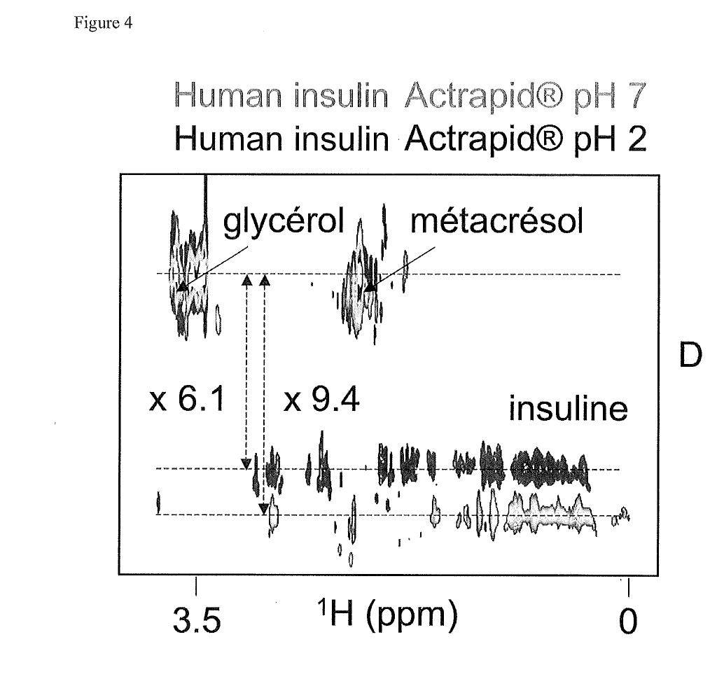

FIG. 4 presents the superposition of the DOSY ¹H maps for the human insulin Actrapid® at pH 7 (light line) and at pH 2 (dark line). The detectable excipients under theses conditions by nuclear magnetic resonance (NMR) are glycerol (C₃H₈O) and metacresol (C₇H₈O).

### EXAMPLES

The present method is usable for any commercial formulation of drug, in particular for the biodrugs and the biosimilars, within the limits of the signal detection of NMR. These limits are in particular fixed by the concentration in therapeutic compound of proteinic nature. As seen previously this method is in particular applicable to the hormonal products (growth hormones, erythropoietin, and insulin), to immunomodulators (beta-interferon), to monoclonal antibodies, to blood coagulation modulators (VIII and IX factors), to enzymes and to vaccines; this list is given as an example and is in no way limited to said list.

If however the commercial formula presented a concentration of protein of interest in insufficient quantity compared to the threshold of detection of the NMR signal, then it would be advisable to increase the field (this example is realized at 600 MHz but one can go up to 800, 900 or 1000 MHz) and/or to use the method of dynamic nuclear polarization (as the one commercialized by Oxford Instrument®) or any other method of increasing the polarization.

A. Insulin

General Information

The amino-acid structure of insulin was the first polypeptidic structure identified by F. Sanger in 1955. The insulin is a peptidic hormone that consists of two peptidic chains: a chain A composed of 21 amino-acids and lacking basic amino-acids and a chain B of 30 amino-acids consisting of basic amino-acids. These two chains are linked with each other by 3 disulfide bonds including two interchain bonds and an intrachain bond within the chain A. In addition, the nature of the amino-acids in position 8, 9 and 10 (in the area of the intrachain bond) is variable according to the animal species.

Insulin is a hypoglycaemic hormone secreted by the pancreas. Its molecular mass (MM) is approximately 6000 and its dimers of MM 12000 are formed easily. These dimers are still likely to join to form polymers of MM 24000 or 48000. This is the oligomeric form of insulin. It is this oligomeric form of insulin that is active.

Formulations of Commercial Insulins

The commercial formulations of insulin currently available contain generally metacresol and zinc ions that allow oligomerization of the protein in the form of a hexamer stable in time (Chang X. et al., Biochemistry, 1997, 36, 9409-9422). Historically isolated starting from pancreas of mammals (beef and pigs), insulin as a therapeutic compound is now produced by techniques known as genetic engineering using the DNA sequence of the human form of the protein. This advance allowed the development of analogs called “fats” or “delayed” of the human insulin making it possible to improve the comfort of the patients. These analogs have an amino-acids sequence which differs from the human sequence. As an example, the lispro insulin commercialized by Eli Lilly® under the trade name Humaolg® presents an amino-acids sequence where the positions of two amino-acids at the end of chain B are reversed (FIG. 1).

Identification of the Type of Insulin

The commercial formulations of insulin contain important concentrations of proteins what allows the fast acquisition of correlation spectra. A spectral signature not-ambiguous can be obtained quickly by measuring a correlation spectrum between the methyl protons and the corresponding carbon. The FIG. 2 shows a superposition of the correlation spectra ¹H-¹³C in the area of the methyl groups measured for the human insulin (Actrapid®, Novo Nordisk) and the lispro insulin (Humalog®, Eli Lilly). The comparison of the spectra clearly shows the consequence of the inversion of the two amin-oacids on the frequency of resonance of the methyl groups. In the case of insulin, the attribution of the frequencies is available what makes it possible to identify the frequencies associated with isoleucine 2 of the chain A as being the more disturbed by the mutation, which is coherent with the three-dimensional structure of insulin (Chang X. et al., Biochemistry, 1997, 36, 9409-9422). This effect of displacement of frequencies allows a non-ambiguous identification of this insulin variant. One shows thus that the use of this type of spectrum makes it possible to distinguish two molecules that have the same composition in amino-acids but from which the amino-acids sequence differs.

Effect of the Galenic Formulation

The frequencies of resonance of the methyl groups are also sensitive to several physicochemical parameters and their environment (temperature, pH, solvent composition). In this example, two therapeutic compositions containing human insulin coming from two different pharmaceutical laboratories are compared (FIG. 3). The protein is identical, but the formulation is slightly different: Actrapid® contains in addition to human insulin, zinc chloride, glycerol, meta-cresol, sodium hydroxide, hydrochloric acid and water for injectable preparations; Umuline rapide® contains, in addition to human insulin, glycerol, meta-cresol, sodium hydroxide, hydrochloric acid, sodium phosphate dibasic heptahydrate and water for injectable preparations. One note that the correlation spectra ¹H-¹³C in the area of the methyls measured for the insulin coming from Novo Nordisk and from Eli Lilly are quasi-stackable, which makes it possible to attest the identity of the two proteins. Weak displacements of frequencies (<20 Hz) are however observed on certain peaks of correlation. This displacement that is linked to a difference in the saline composition of the two formulations, makes it possible to distinguish the source of the drug. The present technique allows also to verify the integrity of the commercial formulation. This integrity can be altered during the manufacturing process or during stages such as the transport and the storage of the insulin formulations. These degradations will inevitably lead to displacement od frequencies of resonance which will be detected in the correlation spectra.

Oligomeric State and Nature of the Excipients

The DOSY ¹H spectra allow also distinguishing the signals coming from the excipients from the signals coming from the therapeutic compound of proteinic nature. The excipients being generally small molecules have a coefficient of diffusion quite higher than that of a protein. The present method make thus possible to detect the presence of excipients listed in the composition of the commercial product. Moreover, it makes it possible to identify potential low molecular weight contaminants and to possibly determine their chemical nature. In the same way, its is possible to estimate the oligomerization state of insulin since its coefficient of diffusion measured on the signals coming from the protein is linked to the number of monomers which join (FIG. 4). Thus, a hexamer will have of coefficient of diffusion lower than that of a dimer, the hexameric form representing the stable form of the insulin. The present method is thus able to determine if the studied commercial formulation presents really a stable form of insulin.

Experimental Method:

The samples used contain human insulin or one of its analogues in a commercial formulation. The insulins available on the French market are dosed at 100 UI/mL, what corresponds to a protein concentration of 3.5 mg/mL. To 500 μL of solution directly taken in the sample, 50 μL of D₂O are added. These 550 μL are placed in a NMR tube of a diameter equal to 5 millimetres. The first stage is the realization of a spectrum SOFAST-HMQC ¹H-¹³C (Schanda P. et al. J. Biomol. NMR, 2005, 33, 199-211) centred in the spectral zone of the methyl groups of a protein. The second step is the realization of a spectrum DOSY ¹H (Balayssac S. et al., J. Magn. Reson. 2009, 196, 78-83). These two spectra are registered on a BRUKER spectrometer operating at 600 MHz (¹H) equipped with a cryogenic probe. The treatment of the spectra is carried out with the software NMRnotebook® (NMRTEC).

B. Growth Hormone (Somatropin)

General Information

This 191 amino-acids protein appears as a powder to reconstitute or directly in solution. The available concentrations are of 5-10 mg/mL allowing considering nuclear magnetic resonance experiments based on the natural abundance of ¹⁵N and of ¹³C. Moreover, its conditioning in the form of powder is ideal for the experiments of ¹H/²H exchanges. Finally there exist biosimilar versions of this hormone that makes it possible to consider a comparative study with the original drug or biodrug.

Formulations of Commercial Somatotropin

The commercial formulations of therapeutic composition subject of he present study are the Omnitrope® (Sandoz) and the Genotonorm® (Pfizer).

Experimental Method:

The used samples contain various forms of somatotropin in two different therapeutic compositions. One put in a nuclear magnetic resonance tube of a diameter equal to 5 millimetres a sample if each composition. The first step is the realization of a SOFAST-HMQC ¹H-¹³C spectrum (Schanda P. et al. J. Biomol. NMR, 2005, 33, 199-211) centered on the spectral zone of the methyl groups of a protein. The second step is the realization of a second Spectrum. Those two spectra are recorded on a BRUKER spectrometer operating at 600 MHz (¹H) equipped with a cryogenic probe. The treatment of the spectra is carried out with the software NMRnotebook® (NMRTEC).

Results

Following the implementation of the method according to the present invention, one can distinguish without ambiguity two different formulations of somatotropin which are the Omnitrope® and the Genotonorm®.

1. Method for the comparative analysis and the quality control of therapeutic compositions, implementing nuclear magnetic resonance (NMR) spectrometry, characterized in that it consists of the following steps:
a) to select at least two different proteinic preparations containing a biodrug;
b) to establish the spectral signature of the biodrug in the first proteinic preparation from at least two spectra of nuclear magnetic resonance;
c) to establish the spectral signature of the biodrug in the second proteinic preparation from at least two spectra of nuclear magnetic resonance;
d) to compare the spectral signatures of the biodrug in the first and in the second proteinic preparations;
e) to determine from the spectral signatures obtained during steps b) and c) if the biodrug is identical in the first proteinic preparation and in the second proteinic preparation.

2. Method of analysis according to claim 1, characterized in that at least one nuclear magnetic resonance spectrum realized during step b) from one selected proteinic preparation implements a two-dimensional nuclear magnetic resonance method (2D NMR).

3. Method of analysis according to claim 1, characterized in that at least one nuclear magnetic resonance spectrum realized during step c) from one selected proteinic preparation implements a two-dimensional nuclear magnetic resonance method (2D NMR).

4. Method of analysis according to any of claim 2 or 3, characterized in that the two-dimensional nuclear magnetic resonance method is selected among the DOSY method, the NOESY, SOFAST, COSY, TOCSY, HSQC, HNCA, HNCO, HNCOCA, HCCH TOCSY HCCH COSY methods improved or not by the TROSY alternative, as well as any recording sequence of nuclear magnetic resonance that allows to establish correlations between two or more cores of the biodrug.

5. Method of analysis according to claim 1, characterized in that it consists of the following steps:
a) to select at least two various proteinic preparations containing a biodrug;
b) to establish the spectral signature of the biodrug in the first proteinic preparation from at least two nuclear magnetic resonance spectra;
c) to establish the spectral signature of the biodrug in the second proteinic preparation from at least two nuclear magnetic resonance spectra, said spectra being realized according to the same methods of nuclear magnetic resonance than during step b);
d) to compare the spectral signatures of the biodrug in the first and in the second proteinic preparation by superposing the spectra realized during steps b) and c);
e) to determine from the spectral signatures obtained during steps b) and c) if the biodrug is identical in the first proteinic preparation and in the second proteinic preparation.

6. Method of analysis according to claim 1, characterized in that at least one spectrum of nuclear magnetic resonance realized during step b) and c) from the selected proteinic preparations implements a two-dimensional method of nuclear magnetic resonance.

7. Method of analysis according to claim 1, characterized in that it consists of the following steps:
a) to select at least two various proteinic preparations containing a biodrug;
b) to realize at least two two-dimensional spectra of nuclear magnetic resonance from the first proteinic preparation;
c) to realize at least two two-dimensional spectra of nuclear magnetic resonance from the second proteinic preparation;
d) to compare the spectral signatures obtained from the first and second proteinic preparations;
e) to determine if the biodrug is identical in the first and in the second proteinic preparations.

8. Method for the comparative analysis of proteinic conformations implementing the nuclear magnetic resonance spectrometry according to claim 1, characterized in that the biodrug is a biosimilar.

9. Method for the comparative analysis of proteinic conformations implementing the nuclear magnetic resonance spectrometry according to any of claims 1 to 7, characterized in that the biodrug is the insulin.

10. Method for the comparative analysis of proteinic conformations implementing the nuclear magnetic resonance spectrometry according to any of claims 1 to 7, characterized in that the biodrug is the growth hormone.
